(19) United States
(12) Patent Application Publication
(10) Pub. No.: US 2016/0274393 A1
(43) Pub. Date: Sep. 22, 2016

(54) DISPLAY PANEL AND THIN FILM TRANSISTOR ARRAY SUBSTRATE

(71) Applicant: SHENZHEN CHINA STAR OPTOELECTRONICS TECHNOLOGY CO., LTD., Guangdong (CN)

(72) Inventor: Yanxi Ye, Guangdong (CN)

(21) Appl. No.: 14/410,449

(22) PCT Filed: Oct. 15, 2014
(86) PCT No.: PCT/CN2014/088608

§ 371 Date: Dec. 22, 2014

(30) Foreign Application Priority Data
Oct. 9, 2014 (CN) 201410528406.7

(51) Int. Cl. G02F 1/1368; H01L 27/12; G02F 1/1362; G02F 1/1335; G02F 1/1343

(52) U.S. Cl. CPC G02F 1/1368; G02F 1/133514; G02F 1/134336; G02F 1/136286; G02F 1/13439; H01L 27/1214

(57) ABSTRACT

A display panel and a thin film transistor (TFT) array substrate are provided. The display panel comprises color filter (CF) substrate, a liquid crystal layer and the TFT array substrate. Each of the pixel units on the TFT array substrate comprises strip-like electrodes and at least one connection electrode including at least two connection portions on an edge thereof, wherein the connection portions are connected to first ends of the strip-like electrodes. A recess array or a projection array is formed on the edge and between each adjacent two of the connection portions. Declination phenomenon can be mitigated.

### FIELD OF THE INVENTION

The present invention relates to a technical field of displays, and more particularly to a display panel and a thin film transistor (TFT) array substrate.

### BACKGROUND OF THE INVENTION

In a conventional TFT liquid crystal display (LCD) panel comprises a plurality of pixel units (including green sub-pixels 101, blue sub-pixels 102, and red sub-pixels 103). A plurality of parallel strip-like electrodes are disposed on the pixel unit, the strip-like electrodes are used for applying a first electric field to drive the liquid crystal molecules, so as to achieve a grayscale conversion.

In practice, there are the following problems existing in the conventional technology:

The strip-like electrodes are disposed in parallel, and a second electric field is formed at the connections of the strip-like electrodes, and a direction of the second electric field is different from a direction of the first electric field. Therefore, the liquid crystal molecules close to the connections cannot be controlled, resulting in a declination phenomenon in the display area 104 corresponding to the connections, as shown in FIG. 1. The larger a driving voltage is, the more obvious the declination phenomenon is, resulting in a reduced transmittance of the display panel, as well as affecting a display quality thereof.

As a result, it is necessary to provide a new technology to solve the problems existing in the conventional technologies, as described above.

### SUMMARY OF THE INVENTION

The present invention provides a display panel and a TFT array substrate for mitigating the declination phenomenon, as well as improving the display quality.

A primary object of the present invention is to provide a display panel, wherein the display panel comprises: a color filter (CF) substrate; a liquid crystal layer; and a TFT array substrate, wherein the TFT array substrate includes at least two pixel units, and the at least two pixel units are arranged in a matrix manner, and each of the pixel units comprises a pixel electrode, and the pixel electrode comprises: at least two strip-like electrodes, wherein each of the strip-like electrodes includes a first end and a second end; and at least one connection electrode including at least two connection portions on the edge thereof, wherein the connection portions are connected to the first ends of the strip-like electrodes; wherein a recess array or a projection array is formed on the edge and between each adjacent two of the connection portions, and the recess array includes at least two recess portions arranged in an array manner, and the projection array includes at least two projection portions arranged in an array manner.

In the above-mentioned display panel, first sub-recess portions or first sub-projection portions are formed on a surface of the recess portions.

In the above-mentioned display panel, second sub-recess portions or second sub-projection portions are formed on a surface of the projection portions.

Another object of the present invention is to provide a display panel, wherein the display panel comprises: a CF substrate; a liquid crystal layer; and a TFT array substrate, wherein the TFT array substrate includes at least two pixel units, and the at least two pixel units are arranged in a matrix manner, and each of the pixel units comprises a pixel electrode, and the pixel electrode comprises: at least two strip-like electrodes, wherein each of the strip-like electrodes includes a first end and a second end; and at least one connection electrode including at least two connection portions on the edge thereof, wherein the connection portions are connected to the first ends of the strip-like electrodes; wherein a recess array or a projection array is formed on the edge and between each adjacent two of the connection portions.

In the above-mentioned display panel, the recess array includes at least two recess portions arranged in an array manner.

In the above-mentioned display panel, first sub-recess portions or first sub-projection portions are formed on a surface of the recess portions.

In the above-mentioned display panel, the first sub-recess portions or the first sub-projection portions are elongated or granular, and the first sub-recess portions or the first sub-projection portions are arranged on the surface of the recess portions, and the first sub-projection portions are formed by sputtering or coating a first conductive material on the surface of the recess portions, and the first sub-recess portions are formed on the surface of the recess portions by etching or cutting.

In the above-mentioned display panel, ends of the recess portions are rounded.

In the above-mentioned display panel, the projection array includes at least two projection portions arranged in an array manner.

In the above-mentioned display panel, second sub-recess portions or second sub-projection portions are formed on a surface of the projection portions.

In the above-mentioned display panel, the second sub-recess portions or the second sub-projection portions are elongated or granular, and the second sub-recess portions or the second sub-projection portions are arranged on the surface of the projection portions, and the second sub-projection portions are formed by sputtering or coating a second conductive material on the surface of the projection portions, and the second sub-recess portions are formed on the surface of the projection portions by etching or cutting.

In the above-mentioned display panel, ends of the projection portions are rounded.

Still another object of the present invention is to provide a TFT array substrate, wherein the TFT array substrate includes at least two pixel units, and the at least two pixel units are arranged in a matrix manner, and each of the pixel units comprises a pixel electrode, and the pixel electrode comprises: at least two strip-like electrodes, wherein each of the strip-like electrodes includes a first end and a second end; and at least one connection electrode including at least two connection portions on the edge thereof, wherein the connection portions are connected to the first ends of the strip-like electrodes; wherein a recess array or a projection array is formed on the edge and between each adjacent two of the connection portions.

In the above-mentioned TFT array substrate, the recess array includes at least two recess portions arranged in an array manner.

In the above-mentioned TFT array substrate, first sub-recess portions or first sub-projection portions are formed on a surface of the recess portions.

In the above-mentioned TFT array substrate, the first sub-recess portions or the first sub-projection portions are elongated or granular, and the first sub-recess portions or the first sub-projection portions are arranged on the surface of the recess portions, and the first sub-projection portions are formed by sputtering or coating a first conductive material on the surface of the recess portions, and the first sub-recess portions are formed on the surface of the recess portions by etching or cutting.

In the above-mentioned TFT array substrate, ends of the recess portions are rounded.

In the above-mentioned TFT array substrate, the projection array includes at least two projection portions arranged in an array manner.

In the above-mentioned TFT array substrate, second sub-recess portions or second sub-projection portions are formed on a surface of the projection portions.

In the above-mentioned TFT array substrate, the second sub-recess portions or the second sub-projection portions are elongated or granular, and the second sub-recess portions or the second sub-projection portions are arranged on the surface of the projection portions, and the second sub-projection portions are formed by sputtering or coating a second conductive material on the surface of the projection portions, and the second sub-recess portions are formed on the surface of the projection portions by etching or cutting.

In comparison to the prior art, the declination phenomenon is greatly mitigated in the present invention. In addition, a transmittance of the display panel of the present invention can be significantly greater than a transmittance of the conventional display.

The structure and the technical means adopted by the present invention to achieve the above-mentioned and other objects can be best understood by referring to the following detailed description of the preferred embodiments and the accompanying drawings.

### DESCRIPTION OF THE DRAWINGS

FIG. 1 is a schematic diagram showing pixel units in a conventional display panel;

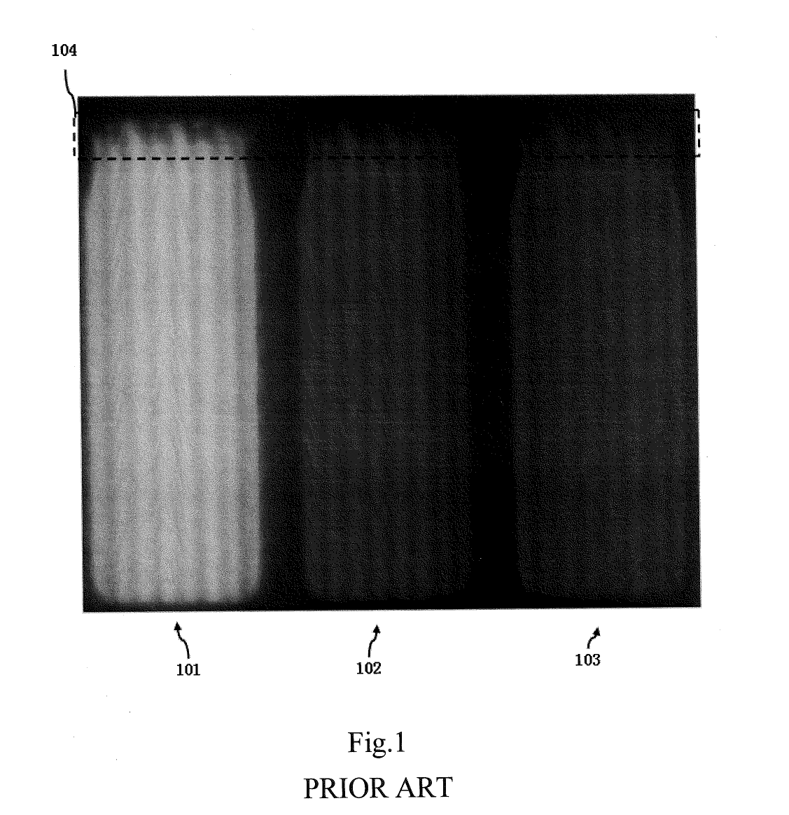

FIG. 2 is a schematic diagram showing pixel units of a display panel according to a first embodiment of the present invention;

FIG. 3 is a schematic diagram showing pixel units of a display panel according to a second embodiment of the present invention;

FIG. 4 is a schematic diagram showing pixel units of a display panel according to a third embodiment of the present invention; and

FIGS. 5a and 5b are schematic diagrams showing the declination phenomenon in a conventional display panel and a display panel of the present invention, respectively.

### DETAILED DESCRIPTION OF THE PREFERRED EMBODIMENTS

The word “embodiment” is used herein to mean serving as an example, instance, or illustration. In addition, the articles “a” and “an” as used in this application and the appended claims may generally be construed to mean “one or more” unless specified otherwise or clear from context to be directed to a singular form.

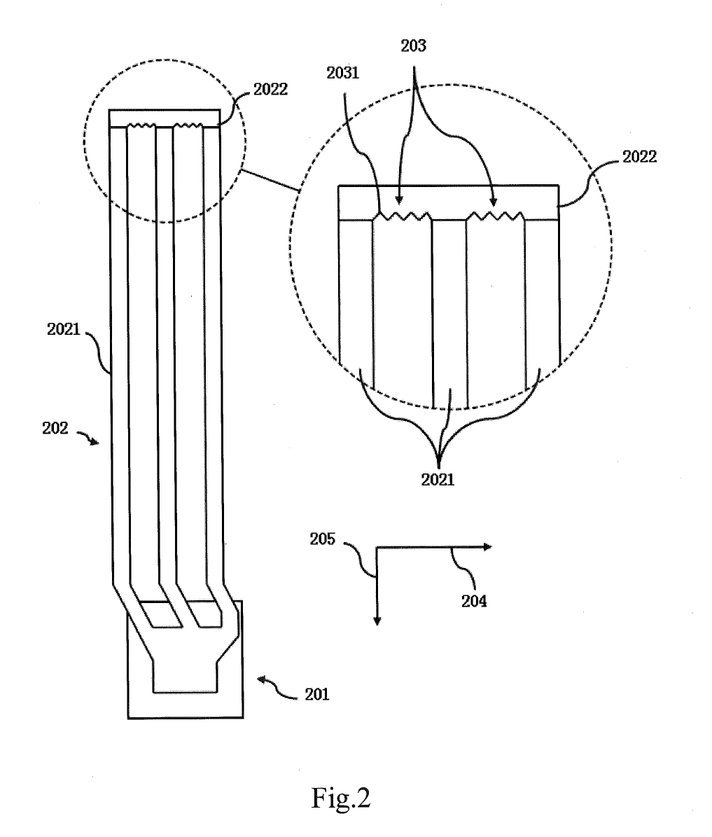

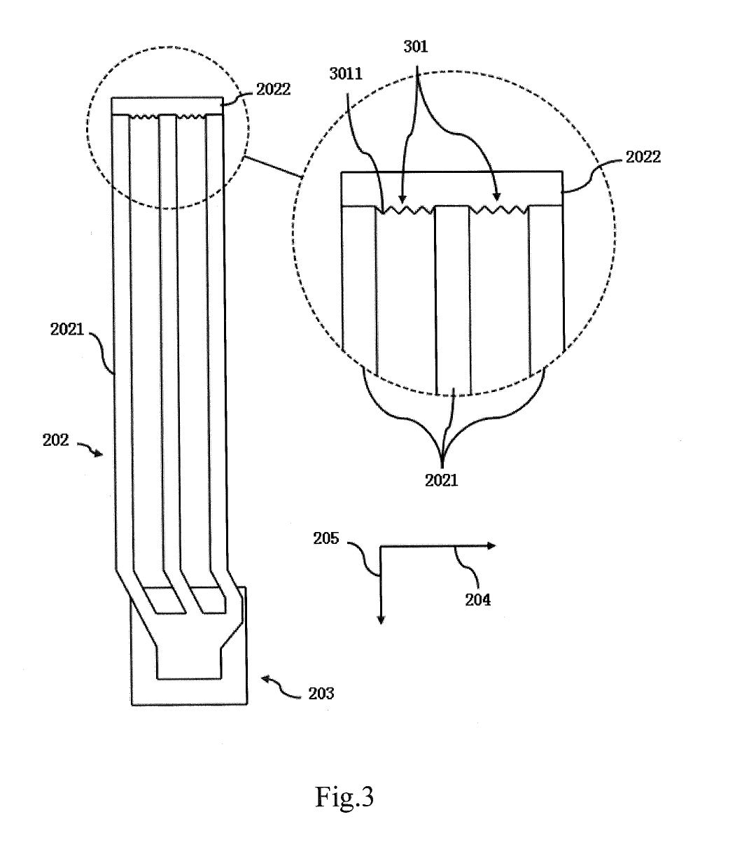

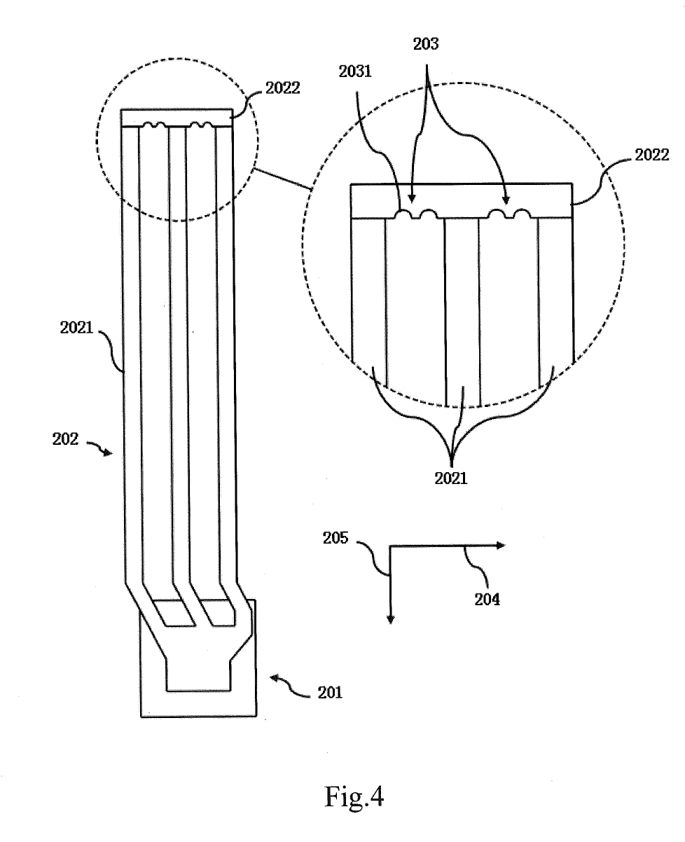

Referring to FIGS. 2, 3, and 4, FIG. 2 is a schematic diagram showing pixel units of a display panel according to a first embodiment of the present invention, and FIG. 3 is a schematic diagram showing pixel units of a display panel according to a second embodiment of the present invention, and FIG. 4 is a schematic diagram showing pixel units of a display panel according to a third embodiment of the present invention.

The display panel of the present invention comprises a thin film transistor (TFT) array substrate, a color filter (CF) substrate, and a liquid crystal layer. The CF substrate is assembled to the TFT array substrate, and the liquid crystal layer is disposed between the TFT array substrate and the CF substrate.

The TFT array substrate includes at least two pixel units, at least two scan lines, and at least two data lines, and the at least two pixel units are arranged in a matrix manner. Each of the pixel units comprises a TFT switch 201 and a pixel electrode 202, and the TFT switch 201 is connected to the pixel electrode 202, the scan lines, and the data lines, wherein the pixel electrode 202 comprises at least two strip-like electrodes 2021 and at least one connection electrode 2022.

Each of the strip-like electrodes 2021 includes a first end and a second end. The connection electrode 2022 includes at least two connection portions on the edge thereof, and the connection portions of the connection electrode 2022 are connected to the strip-like electrodes 2021. The connection portions are connected to the first ends of the strip-like electrodes 2021 and positioned far away from the second ends thereof.

In this embodiment, a curved edge (or curved portion) is formed between each adjacent two of the connection portions of the connection electrode 2022, and the curve of the curved edge may be a regular or irregular curve, wherein curve of the curved edge is formed on the edge of the connection electrode on a first surface. That is, a recess array 203 is formed on the edge and between each adjacent two of the connection portions, as shown in FIGS. 2 and 4. Alternatively, a projection array 301 may be formed on the edge and between each adjacent two of the connection portions, as shown in FIG. 3.

The recess array 203 or the projection array 301 can be formed by etching or cutting, and the recess array 203 or the projection array 301 can be simultaneously formed in the process of forming the connection electrode 2022.

The shape of the recess array 203 on a second surface or the projection array 301 on a third surface may be a saw-toothed shape. The first surface, the second surface, and the third surface are parallel to the surface of the TFT array substrate.

The recess array 203 includes at least two recess portions 2031, and the shape of each of the recess portions 2031 may be triangular (as shown in FIG. 2) or semi-circular (as shown in FIG. 4). The at least two recess portions 2031 are arranged in an array manner, and the at least two recess portions 2031 are arranged along a first direction 204. The first direction 204 is parallel to a longitudinal direction of the connection electrode 2022. The recess portions 2031 are recessed toward a recessed direction, and the recessed direction is parallel to a second direction 205, and the second direction 205 is perpendicular to the first direction 204. That is, the recessed direction of the recess portions 2031 is perpendicular to an outside edge of the connection electrode 2022.

In the present invention, the connection electrode 2022 can comprise the recess array 203 including the at least two recess portions 2031 in the first direction 204. The electric fields in the second direction 205 formed by the at least two recess portions 2031 can be offset by each other, thereby mitigating the declination phenomenon.

In one embodiment, first sub-recess portions or first sub-projection portions can be formed on a surface of the recess portions 2031. The first sub-recess portions or the first sub-projection portions may be elongated or granular. The first sub-recess portions or the first sub-projection portions are arranged on the surface of the recess portions 2031. The first sub-projection portions can be formed by sputtering or coating a first conductive material on the surface of the recess portions 2031. The first sub-recess portions can be formed on the surface of the recess portions 2031 by etching or cutting.

The profile of the recess portions 2031 may be a continuous curve. Namely, the ends of the recess portions 2031 may be rounded or smooth for uniformly distributing the charges on the surface of the recess portions 2031.

The projection array 301 includes at least two projection portions 3011, and the shape of each of the projection portions 3011 may be triangular, as shown in FIG. 3. The at least two projection portions 3011 are arranged in an array manner, and the at least two projection portions 3011 are arranged along the first direction 204. The projection portions 3011 are projected toward a projected direction, and the projected direction is parallel to the second direction 205. That is, the projected direction of the projection portions 3011 is perpendicular to an outside edge of the connection electrode 2022.

In the present invention, the connection electrode 2022 can comprise the projection array 301 including the at least two projection portions 3011 in the first direction 204. The electric fields in the second direction 205 formed by the at least two projection portions 3011 can be offset by each other, thereby mitigating the declination phenomenon.

In one embodiment, second sub-recess portions or second sub-projection portions can be formed on a surface of the projection portions 3011. The second sub-recess portions or the second sub-projection portions may be elongated or granular. The second sub-recess portions or the second sub-projection portions are arranged on the surface of the projection portions 3011. The second sub-projection portions can be formed by sputtering or coating a second conductive material on the surface of the projection portions 3011. The second sub-recess portions can be formed on the surface of the projection portions 3011 by etching or cutting.

The profile of the projection portions 3011 may be a continuous curve. Namely, the ends of the projection portions 3011 may be rounded or smooth for uniformly distributing the charges on the surface of the projection portions 3011.

With the use of the present invention, when a gray-scale voltage inputted to the pixel electrode 202 is higher, a transmittance of the display panel of the present invention can be significantly greater than a transmittance of the conventional display, as shown in Table 1.

TABLE 1
transmittances corresponding to different gray-scale voltages

| | transmittance | |
|---|---|---|
| gray-scale voltage (V) | conventional display | the present invention |
| 0 | 0.023% to 0.038% | 0.023% to 0.038% |
| 0.5 | 0.025% to 0.036% | 0.025% to 0.036% |
| 1 | 0.053% to 0.067% | 0.053% to 0.067% |
| 1.5 | 0.032% to 0.063% | 0.032% to 0.063% |
| 2 | 2.26% to 2.63% | 2.26% to 2.63% |
| 2.5 | 6.24% to 6.66% | 6.2% to 6.59% |
| 3 | 9.98% to 11.13% | 9.99% to 11.15% |
| 3.5 | 12.62% to 13.24% | 12.64% to 13.26% |
| 4 | 14.19% to 14.76% | 14.22% to 14.8% |
| 4.5 | 14.58% to 15.53% | 14.63% to 15.58% |
| 5 | 14.64% to 15.39% | 14.67% to 15.43% |
| 5.5 | 14.27% to 14.84% | 14.29% to 14.87% |
| 6 | 13.65% to 14.43% | 13.66% to 14.46% |

As shown in Table 1, in comparison with the conventional display, the higher the gray-scale voltage is, the greater the transmittance of the display panel of the present invention is.

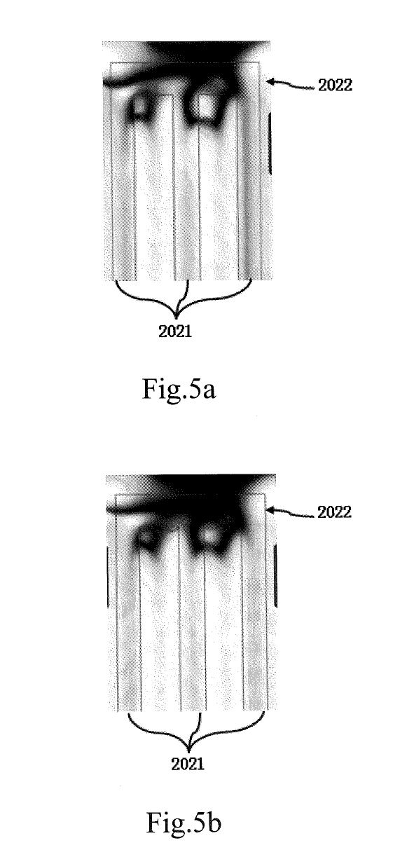

In addition, referring to FIGS. 5a and 5b, FIG. 5a is a schematic diagram showing the declination phenomenon in a display panel without the recess array or the projection array, and FIG. 5b is a schematic diagram showing the declination phenomenon in a display panel having the recess array or the projection array. As shown in FIGS. 5a and 5b, in comparison with the conventional display, the declination phenomenon is greatly mitigated in the present invention, thereby improving the display quality of the display panel.

Although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

The present invention has been described above with a preferred embodiment thereof, and it is understood that many changes and modifications to the described embodiment can be carried out without departing from the scope and the spirit of the invention that is intended to be limited only by the appended claims.

1. A display panel, wherein the display panel comprises:
a color filter (CF) substrate;
a liquid crystal layer; and
a thin film transistor (TFT) array substrate, wherein the TFT array substrate includes at least two pixel units, and the at least two pixel units are arranged in a matrix manner, and each of the pixel units comprises a pixel electrode, and the pixel electrode comprises:
at least two strip-like electrodes, wherein each of the strip-like electrodes includes a first end and a second end; and
at least one connection electrode including at least two connection portions on an edge thereof, wherein the connection portions are connected to the first ends of the strip-like electrodes;
wherein a recess array or a projection array is formed on the edge and between each adjacent two of the connection portions, and the recess array includes at least two recess portions arranged in an array manner, and the projection array includes at least two projection portions arranged in an array manner.

2. The display panel according to claim 1, wherein first sub-recess portions or first sub-projection portions are formed on a surface of the recess portions.

3. The display panel according to claim 1, wherein second sub-recess portions or second sub-projection portions are formed on a surface of the projection portions.

4. A display panel, wherein the display panel comprises:
a CF substrate;
a liquid crystal layer; and
a TFT array substrate, wherein the TFT array substrate includes at least two pixel units, and the at least two pixel units are arranged in a matrix manner, and each of the pixel units comprises a pixel electrode, and the pixel electrode comprises:
at least two strip-like electrodes, wherein each of the strip-like electrodes includes a first end and a second end; and
at least one connection electrode including at least two connection portions on the edge thereof, wherein the connection portions are connected to the first ends of the strip-like electrodes;
wherein a recess array or a projection array is formed on the edge and between each adjacent two of the connection portions.

5. The display panel according to claim 4, wherein the recess array includes at least two recess portions arranged in an array manner.

6. The display panel according to claim 5, wherein first sub-recess portions or first sub-projection portions are formed on a surface of the recess portions.

7. The display panel according to claim 6, wherein the first sub-recess portions or the first sub-projection portions are elongated or granular, and the first sub-recess portions or the first sub-projection portions are arranged on the surface of the recess portions, and the first sub-projection portions are formed by sputtering or coating a first conductive material on the surface of the recess portions, and the first sub-recess portions are formed on the surface of the recess portions by etching or cutting.

8. The display panel according to claim 7, wherein ends of the recess portions are rounded.

9. The display panel according to claim 4, wherein the projection array includes at least two projection portions arranged in an array manner.

10. The display panel according to claim 9, wherein second sub-recess portions or second sub-projection portions are formed on a surface of the projection portions

11. The display panel according to claim 10, wherein the second sub-recess portions or the second sub-projection portions are elongated or granular, and the second sub-recess portions or the second sub-projection portions are arranged on the surface of the projection portions, and the second sub-projection portions are formed by sputtering or coating a second conductive material on the surface of the projection portions, and the second sub-recess portions are formed on the surface of the projection portions by etching or cutting.

12. The display panel according to claim 11, wherein ends of the projection portions are rounded.

13. A TFT array substrate, wherein the TFT array substrate includes at least two pixel units, and the at least two pixel units are arranged in a matrix manner, and each of the pixel units comprises a pixel electrode, and the pixel electrode comprises:
at least two strip-like electrodes, wherein each of the strip-like electrodes includes a first end and a second end; and
at least one connection electrode including at least two connection portions on the edge thereof, wherein the connection portions are connected to the first ends of the strip-like electrodes;
wherein a recess array or a projection array is formed on an edge and between each adjacent two of the connection portions.

14. The TFT array substrate according to claim 13, wherein the recess array includes at least two recess portions arranged in an array manner.

15. The TFT array substrate according to claim 14, wherein first sub-recess portions or first sub-projection portions are formed on a surface of the recess portions.

16. The TFT array substrate according to claim 15, wherein the first sub-recess portions or the first sub-projection portions are elongated or granular, and the first sub-recess portions or the first sub-projection portions are arranged on the surface of the recess portions, and the first sub-projection portions are formed by sputtering or coating a first conductive material on the surface of the recess portions, and the first sub-recess portions are formed on the surface of the recess portions by etching or cutting.

17. The TFT array substrate according to claim 16, wherein ends of the recess portions are rounded.

18. The TFT array substrate according to claim 13, wherein the projection array includes at least two projection portions arranged in an array manner.

19. The TFT array substrate according to claim 18, wherein second sub-recess portions or second sub-projection portions are formed on a surface of the projection portions

20. The TFT array substrate according to claim 19, wherein the second sub-recess portions or the second sub-projection portions are elongated or granular, and the second sub-recess portions or the second sub-projection portions are arranged on the surface of the projection portions, and the second sub-projection portions are formed by sputtering or coating a second conductive material on the surface of the projection portions, and the second sub-recess portions are formed on the surface of the projection portions by etching or cutting.
